(19) United States
(12) Patent Application Publication
(10) Pub. No.: US 2025/0037919 A1
(43) Pub. Date: Jan. 30, 2025

(54) ELECTRONIC COMPONENT

(71) Applicant: Murata Manufacturing Co., Ltd., Kyoto (JP)

(72) Inventor: Yasushi SHIGENO, Kyoto (JP)

(21) Appl. No.: 18/768,264

(22) Filed: Jul. 10, 2024

(30) Foreign Application Priority Data
Jul. 28, 2023 (JP) 2023-123074

(51) Int. Cl. H01F 17/00; H03H 7/01

(52) U.S. Cl. CPC H01F 17/0013; H03H 7/0115; H01F 2017/0026

(57) ABSTRACT

In an electronic component, a first inductor includes a spiral-shaped first conductor pattern portion. A second inductor includes a spiral-shaped second conductor pattern portion. An insulating layer includes an interlayer insulating film that covers the first inductor and a second conductor pattern portion of the second inductor is provided on the interlayer insulating film. The second conductor pattern portion of the second inductor includes a first portion that overlaps the first conductor pattern portion of the first inductor and a second portion that does not overlap the first conductor pattern portion of the first inductor in plan view in the thickness direction of the substrate. The second inductor includes a third conductor pattern portion formed in the interlayer insulating film, and at least a portion of the third conductor pattern portion overlaps the second portion of the second conductor pattern portion.

### CROSS REFERENCE TO RELATED APPLICATION

This application claims priority from Japanese Patent Application No. 2023-123074 filed on Jul. 28, 2023. The content of this application is incorporated herein by reference in its entirety.

### BACKGROUND ART

The present disclosure relates to an electronic component, and more particularly, to an electronic component including a plurality of inductors.

International Publication No. 2011/092910 discloses a thin-film element (electronic component) including a Si substrate, a first insulating film formed on the front surface of the Si substrate, two inductor electrodes formed on the first insulating film each having a spiral pattern, and a second insulating film formed on the two inductor electrodes.

In the thin-film element disclosed in International Publication No. 2011/092910, the two inductor electrodes are spaced apart from each other on the first insulating film.

### BRIEF SUMMARY

In the thin-film element disclosed in International Publication No. 2011/092910, since two inductor electrodes are spaced apart from each other on a first insulation film, the size of the thin-film element may become greater.

The present disclosure provides an electronic component that can achieve size reduction while reducing characteristic degradation.

An electronic component according to an aspect of the present disclosure includes a substrate, an insulating layer, a first inductor, and a second inductor. The insulating layer is provided on the substrate. The first inductor includes a spiral-shaped first conductor pattern portion provided in the insulating layer. The second inductor includes a spiral-shaped second conductor pattern portion provided in the insulating layer. The insulating layer includes an interlayer insulating film that covers the first inductor, and the second conductor pattern portion of the second inductor is provided on the interlayer insulating film. The second conductor pattern portion of the second inductor includes a first portion that overlaps the first conductor pattern portion of the first inductor in plan view in a thickness direction of the substrate and a second portion that does not overlap the first conductor pattern portion of the first inductor in plan view in the thickness direction of the substrate. The second inductor includes a third conductor pattern portion that is formed in the interlayer insulating film, at least a portion of the third conductor pattern portion overlapping the second portion of the second conductor pattern portion.

The electronic component according to the embodiment of the present disclosure can achieve size reduction while reducing characteristic degradation.

### BRIEF DESCRIPTION OF THE DRAWINGS

FIG. 1 is a cross-sectional view of an electronic component according to a first embodiment;

FIG. 2 is a perspective view of the electronic component;

FIG. 3 is a plan view of the electronic component;

FIG. 4 is a bottom view of the electronic component;

FIG. 5A is a plan view transparently illustrating a first metal pattern portion of the electronic component;

FIG. 5B is a plan view transparently illustrating a second metal pattern portion of the electronic component;

FIG. 5C is a plan view transparently illustrating a third metal pattern portion of the electronic component;

FIG. 5D is a plan view transparently illustrating a fourth metal pattern portion of the electronic component;

FIG. 5E is a plan view transparently illustrating a fifth metal pattern portion of the electronic component;

FIG. 5F is a plan view transparently illustrating a sixth metal pattern portion of the electronic component;

FIG. 6 is a circuit diagram of the electronic component;

FIG. 7 is an equivalent circuit diagram of the electronic component;

FIG. 8 is a characteristic diagram of the electronic component; and

FIG. 9 is a cross-sectional view of an electronic component according to a second embodiment.

### DETAILED DESCRIPTION

First and second embodiments and the like will be described with reference to the drawings. The drawings referenced by embodiments described below are schematic, and the sizes and the thicknesses of components in the drawings do not necessarily reflect actual dimensions, and the ratio of sizes and the ratio of thicknesses between components do not necessarily reflect actual dimensional ratios.

### First Embodiment

An electronic component 100 according to a first embodiment will be described with reference to the drawings.

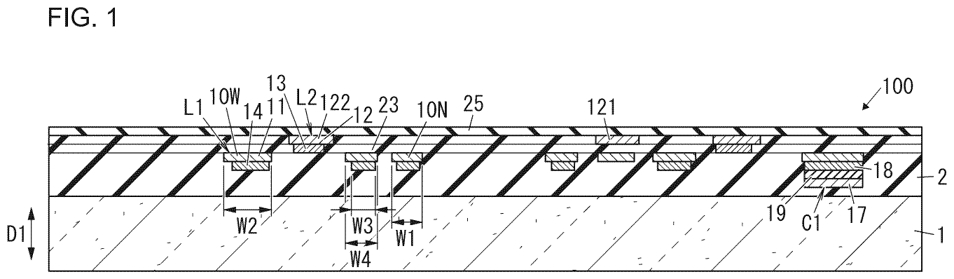

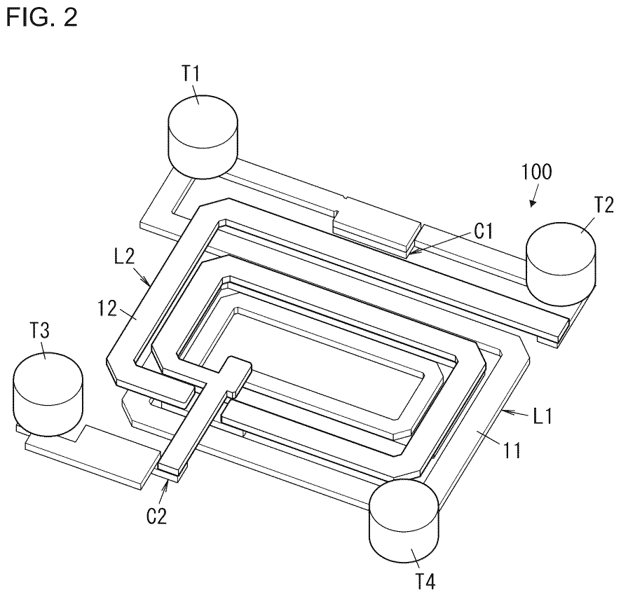

The electronic component 100 according to the first embodiment includes a first inductor L1 and a second inductor L2 as illustrated in FIGS. 1 and 2. The electronic component 100 is, for example, an integrated passive device (IPD).

The electronic component 100 includes an LC filter used for, for example, communication devices. Such a communication device is, for example, a mobile phone (for example, a smartphone) but is not limited to this and may be, for example, a wearable terminal (for example, a smart watch) or the like.

### 1 Circuit Structure of Electronic Component

The circuit structure of the electronic component 100 according to the first embodiment will be described below with reference to the drawings.

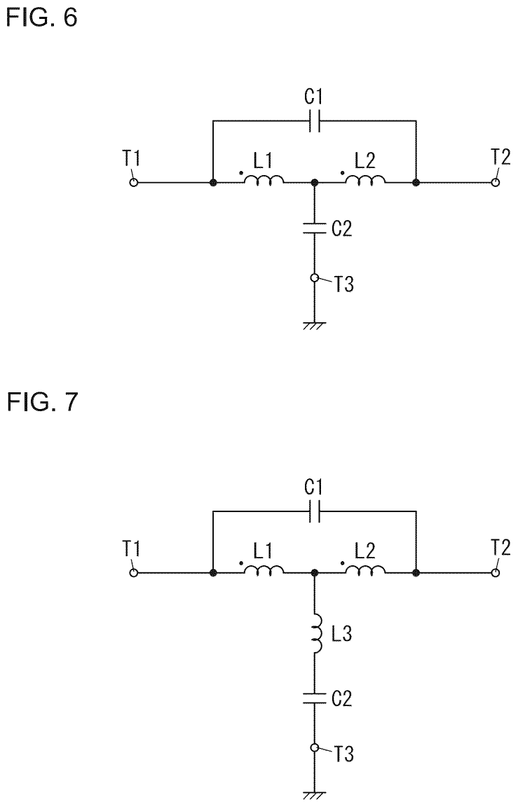

As illustrated in FIG. 6, the electronic component 100 includes an input terminal T1, an output terminal T2, a ground terminal T3, a first inductor L1, a second inductor L2, a capacitor C1 (also referred to below as a first capacitor C1), and a capacitor C2 (also referred to below as a second capacitor C2). The first capacitor C1 and the second capacitor C2 are included in the LC filter together with the first inductor L1 and the second inductor L2. The LC filter included in the electronic component 100 serves as a low-pass filter.

The input terminal T1 is a terminal to which a high frequency signal is input. The output terminal T2 is a terminal from which a high frequency signal having passed through the LC filter is output. The ground terminal T3 is a terminal connected to, for example, a ground conductor portion of a circuit board on which the electronic component 100 is disposed.

The first inductor L1 has a first end and a second end, and the second inductor L2 has a first end and a second end. In the electronic component 100, the first end of the first inductor L1 and the first end of the second inductor L2 are connected to each other, the second end of the first inductor L1 is connected to the input terminal T1, and the second end of the second inductor L2 is connected to the output terminal T2. In the electronic component 100, the first inductor L1 and the second inductor L2 are cumulatively connected to each other.

The first capacitor C1 has a first end and a second end, and the second capacitor C2 has a first end and a second end. In the electronic component 100, the first end of the first capacitor C1 is connected to the input terminal T1, and the second end of the capacitor C1 is connected to the output terminal T2. In the electronic component 100, the first end of the second capacitor C2 is connected to the first end of the first inductor L1 and the first end of the second inductor L2, and the second end of the second capacitor is connected to the ground terminal T3.

### 2 Equivalent Circuit of Electronic Component

In the equivalent circuit illustrated in FIG. 7, the mutual inductance between the first inductor L1 and the second inductor L2 is illustrated as an inductor L3 connected between the second capacitor C2 and a connection point between the first inductor L1 and the second inductor L2.

In the electronic component 100, since the first inductor L1 and the second inductor L2 are cumulatively connected to each other, the inductor L3 need not be formed separately from the first inductor L1 and the second inductor L2.

### 3 Structure of Electronic Component

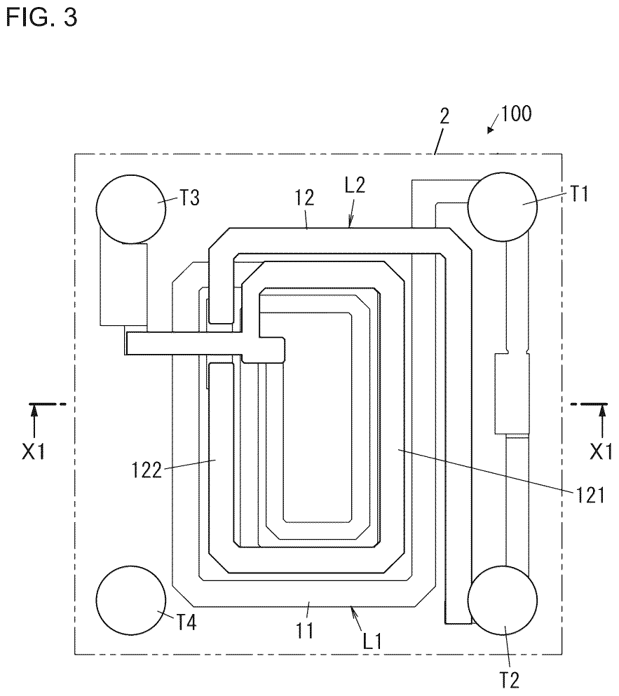

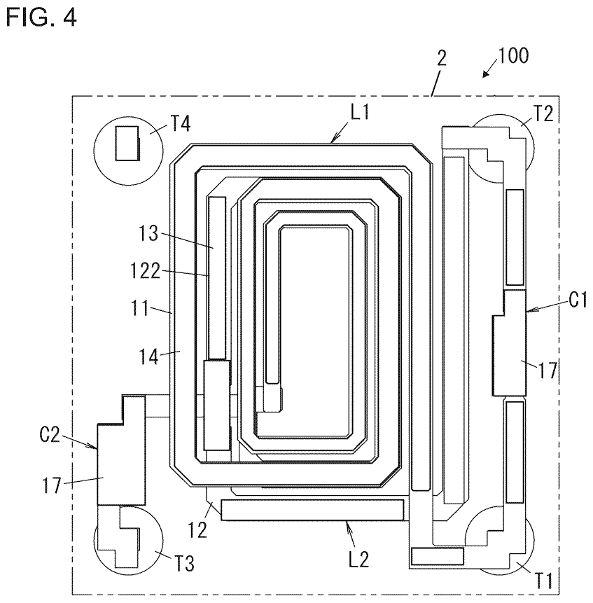

As illustrated in FIG. 1, the electronic component 100 includes a substrate 1, an insulating layer 2, the first inductor L1, the second inductor L2, the first capacitor C1, and the second capacitor C2 (see FIG. 2). The electronic component 100 further includes the input terminal T1, the output terminal T2, the ground terminal T3, and a terminal T4, as illustrated in FIGS. 2 and 3. In FIGS. 2 to 4, the substrate 1 and the insulating layer 2 are not illustrated. FIG. 1 is a cross-sectional view corresponding to a cross section taken along line X1-X1 in FIG. 3.

The substrate 1 is, for example, a silicon substrate. The substrate 1 is not limited to a silicon substrate and may be, for example, a glass substrate. In plan view in a thickness direction D1 of the substrate 1, the outer edge of the substrate 1 has, for example, a rectangular shape but may have a shape other than a rectangular shape. The thickness of the substrate 1 is, for example, 80 μm or greater and 380 μm or less.

The insulating layer 2 is provided on the substrate 1. The insulating layer 2 is thinner than the substrate 1. The thickness of the insulating layer 2 is, for example, 20 μm or less. Accordingly, the thickness of the electronic component 100 can be 400 μm or less. However, the thickness of the electronic component 100 is not limited to 400 μm or less and may be greater than 400 μm.

The insulating layer 2 is electrically insulated. The insulating layer 2 has a multi-layer structure and includes an interlayer insulating film 23 and a protective film 25. The interlayer insulating film 23 is disposed between the first inductor L1 and the second inductor L2 in the thickness direction D1 of the substrate 1. The interlayer insulating film 23 covers the first inductor L1. The material of the interlayer insulating film 23 contains, for example, silicon oxide. The protective film 25 is a passivation film. The material of the protective film 25 contains, for example, silicon nitride. It should be noted that the material of a portion of the insulating layer 2 other than the protective film 25 includes, for example, silicon oxide.

The first inductor L1 is spiral-shaped in plan view in the thickness direction D1 of the substrate 1 (see FIG. 3). The first inductor L1 includes a spiral-shaped first conductor pattern portion 11 provided in the insulating layer 2. The first conductor pattern portion 11 is electrically conductive. The material of the first conductor pattern portion 11 contains a metal. The thickness of the first conductor pattern portion 11 is, for example, 3 μm but is not limited to 3 μm.

The second inductor L2 is spiral-shaped in the thickness direction D1 of the substrate 1 (see FIG. 3). The second inductor L2 includes a spiral-shaped second conductor pattern portion 12 provided in the insulating layer 2. The second conductor pattern portion 12 is electrically conductive. The material of the second conductor pattern portion 12 contains a metal. The thickness of the second conductor pattern portion 12 is, for example, 3 μm but is not limited to 3 μm.

The second conductor pattern portion 12 of the second inductor L2 is provided on the interlayer insulating film 23. The second conductor pattern portion 12 of the second inductor L2 has a first portion 121 that overlaps the first conductor pattern portion 11 of the first inductor L1 in plan view in the thickness direction D1 of the substrate 1 and a second portion 122 that does not overlap the first conductor pattern portion 11 of the first inductor L1 in plan view in the thickness direction D1 of the substrate 1.

The second inductor L2 includes a third conductor pattern portion 13. The third conductor pattern portion 13 is formed in the interlayer insulating film 23, and at least a portion of the third conductor pattern portion 13 overlaps the second portion 122 of the second conductor pattern portion 12. The third conductor pattern portion 13 is disposed in a cavity passing through the interlayer insulating film 23 in the thickness direction D1 of the substrate 1. The third conductor pattern portion 13 is electrically conductive. The material of the third conductor pattern portion 13 contains a metal. The thickness of the third conductor pattern portion 13 is, for example, 3 μm but is not limited to 3 μm. It should be noted that the third conductor pattern portion 13 may be disposed in a spiral recess formed in the interlayer insulating film 23.

In the electronic component 100, the first inductor L1 further includes a fourth conductor pattern portion 14. The fourth conductor pattern portion 14 is formed in the interlayer insulating film 23. The fourth conductor pattern portion 14 overlaps a portion of the first conductor pattern portion 11 that does not overlap the second conductor pattern portion 12 of the second inductor L2 in plan view in the thickness direction D1 of the substrate 1. The fourth conductor pattern portion 14 is electrically conductive. The material of the fourth conductor pattern portion 14 includes a metal. The thickness of the fourth conductor pattern portion 14 is, for example, 3 μm but is not limited to 3 μm.

In addition, in the electronic component 100, in plan view in the thickness direction D1 of the substrate 1, a plurality of portions of the second conductor pattern portion 12 and a plurality of portions of the first conductor pattern portion 11 are arranged alternately in the width direction of the second conductor pattern portion 12 and the first conductor pattern portion 11, as illustrated in FIG. 3.

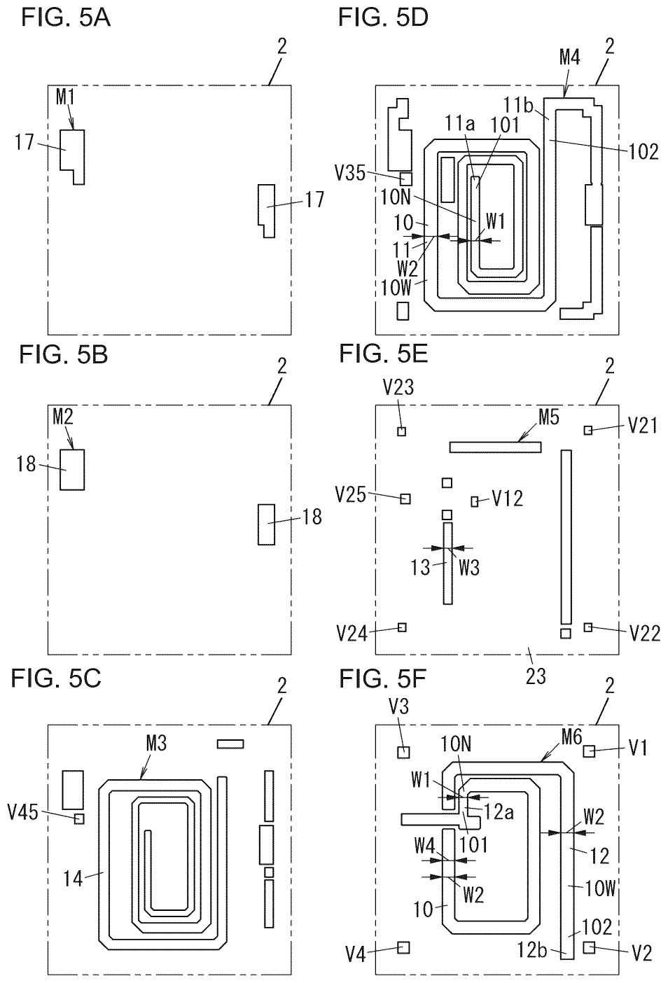

In addition, in the electronic component 100, the conductor pattern portion 10 that is the first conductor pattern portion 11 includes a narrow portion 10N having a first width W1 (see FIG. 1) and a wide portion 10W having a second width W2 (see FIG. 1) greater than the first width W1, as illustrated in FIG. 5D. Of a first end 101 and a second end 102 of the conductor pattern portion 10, the first end 101 is closer to the center, and the narrow portion 10N has the first end 101. The wide portion 10W includes the second end 102. In the electronic component 100, a portion of the first inductor L1 that overlaps the first portion 121 of the second conductor pattern portion 12 of the second inductor L2 includes a portion of the narrow portion 10N.

In addition, in the electronic component 100, the conductor pattern portion 10 that is the second conductor pattern portion 12 includes the narrow portion 10N having the first width W1 and the wide portion 10W having the second width W2 greater than the first width W1, as illustrated in FIG. 5F. Of the first end 101 and the second end 102 of the conductor pattern portion 10, the first end 101 is closer to the center, and the narrow portion 10N has the first end 101. The wide portion 10W includes the second end 102. In the electronic component 100, the first portion 121 of the second conductor pattern portion 12 of the second inductor L2 includes a portion of the narrow portion 10N.

The electronic component 100 further includes a via conductor V12 (see FIG. 5E) disposed between the first inductor L1 and the second inductor L2. The via conductor V12 is formed in the interlayer insulating film 23. In the electronic component 100, the first inductor L1 and the second inductor L2 are cumulatively connected to each other by the via conductor V12.

In the electronic component 100, the area of the first portion 121 of the second conductor pattern portion 12 is less than the area of the second portion 122 of the second conductor pattern portion 12 in plan view in the thickness direction D1 of the substrate 1 (see FIG. 3).

In the electronic component 100, the first conductor pattern portion 11 has a first end 11a closer to the center and a second end 11b closer to the outer periphery, as illustrated in FIG. 5D. The first end 11a and the second end 11b of the first conductor pattern portion 11 correspond to the first end 101 and the second end 102 of the conductor pattern portion 10 that constitutes the first conductor pattern portion 11. In addition, as illustrated in FIG. 5F, the second conductor pattern portion 12 has a first end 12a closer to the center and a second end 12b closer to the outer periphery. The first end 12a and the second end 12b of the second conductor pattern portion 12 correspond to the first end 101 and the second end 102 of the conductor pattern portion 10 that constitutes the second conductor pattern portion 12.

In the electronic component 100, the second portion 122 (see FIG. 1) of the second conductor pattern portion 12 of the second inductor L2 is closer to the second end 12b than to the first end 12a.

In the electronic component 100, in plan view in the thickness direction D1 of the substrate 1, a width W3 (see FIGS. 1 and 5E) of the third conductor pattern portion 13 is less than a width W4 (see FIGS. 1 and 5F) of the first conductor pattern portion 11 in the second portion 122 of the second conductor pattern portion 12 of the second inductor L2.

The first capacitor C1 and the second capacitor C2 are provided in the insulating layer 2. As illustrated in FIG. 1, each of the first capacitor C1 and the second capacitor C2 has a pair of electrodes 17 and 18 and a dielectric film 19 disposed between the pair of electrodes 17 and 18. In the thickness direction D1 of the substrate 1, the electrode 17, the dielectric film 19, and the electrode 18 of each of the first capacitor C1 and the capacitor C2 are arranged in this order in a direction away from the substrate 1. That is, the dielectric film 19 is stacked on the electrode 17, and the electrode 18 is stacked on the dielectric film 19. In the thickness direction D1 of the substrate 1, the pair of electrodes 17 and 18 of the capacitors C1 and C2 are located closer to the substrate 1 than is the first inductor L1. The thickness of the electrode 17 is, for example, 0.6 μm but is not limited to 0.6 μm. In addition, the thickness of the dielectric film 19 is, for example, 0.1 μm but is not limited to 0.1 μm. In addition, the thickness of the electrode 18 is, for example, 0.2 μm but is not limited to 0.2 μm.

In the electronic component 100, in plan view in the thickness direction D1 of the substrate 1, the pair of electrodes 17 and 18 of each of the first capacitor C1 and the second capacitor C2 does not overlap the first inductor L1 or the second inductor L2.

In the electronic component 100, in plan view in the thickness direction D1 of the substrate 1, the pair of electrodes 17 and 18 of each of the first capacitor C1 and the second capacitor C2 are located outside the second inductor L2.

As illustrated in FIGS. 5A to 5F, the electronic component 100 includes a first metal pattern portion M1, a second metal pattern portion M2, a third metal pattern portion M3, a fourth metal pattern portion M4, a fifth metal pattern portion M5, and a sixth metal pattern portion M6. The first metal pattern portion M1, the second metal pattern portion M2, the third metal pattern portion M3, the fourth metal pattern portion M4, the fifth metal pattern portion M5 and the sixth metal pattern portion M6 are disposed in the insulating layer 2. In the thickness direction D1 of the substrate 1, the first metal pattern portion M1, the second metal pattern portion M2, the third metal pattern portion M3, the fourth metal pattern portion M4, the fifth metal pattern portion M5, and the sixth metal pattern portion M6 are located in this order in a direction away from the substrate 1.

As illustrated in FIG. 5A, the first metal pattern portion M1 includes one electrode 17 of the first capacitor C1 and one electrode 17 of the second capacitor C2. As illustrated in FIG. 5B, the second metal pattern portion M2 includes the other electrode 18 of the first capacitor C1 and the other electrode 18 of the second capacitor C2. As illustrated in FIG. 5C, the third metal pattern portion M3 includes the fourth conductor pattern portion 14 and a via conductor V45 connected to the electrode 17. As illustrated in FIG. 5D, the fourth metal pattern portion M4 includes the first conductor pattern portion 11 and a via conductor V35 connected to the via conductor V45. As illustrated in FIG. 5E, the fifth metal pattern portion M5 includes the third conductor pattern portion 13, a via conductor V25 connected to the via conductor V35, a via conductor V21 connected to the input terminal T1, a via conductor V22 connected to the output terminal T2, a via conductor V23 connected to the ground terminal T3, and a via conductor V24 connected to terminal T4. As illustrated in FIG. 5F, the sixth metal pattern portion M6 includes the second conductor pattern portion 12, a via conductor V1 connected to the input terminal T1 and the via conductor V21, a via conductor V2 connected to the output terminal T2 and the via conductor V22, a via conductor V3 connected to the ground terminal T3 and the via conductor V23, and the via conductor V2 connected to the terminal T4 and the via conductor V24.

In the electronic component 100, as illustrated in FIG. 2, the first inductor L1 and the second inductor L2 are disposed such that a magnetic field generated by the first inductor L1 and a magnetic field generated by the second inductor L2 are coupled to each other. The first inductor L1 and the second inductor L2 are disposed such that the first inductor L1 and the second inductor L2 are coupled to each other.

In the electronic component 100, the winding direction of the first inductor L1 is opposite to the winding direction of the second inductor L2, and, in the thickness direction D1 of a mounting substrate 9, a portion of the first inductor L1 overlaps a portion of the second inductor L2.

### 4 Manufacturing Method

In the manufacturing method of the electronic component 100 according to the first embodiment, a wafer that is a base of the substrate 1 is prepared, the insulating layer 2, the first metal pattern portion M1, the second metal pattern portion M2, the third metal pattern portion M3, the fourth metal pattern portion M4, the fifth metal pattern portion M5, and the sixth metal pattern portion M6 are formed by using a thin film formation technique, a photolithography technique, an etching technique, and the like, and the input terminal T1, the output terminal T2, the ground terminal T3, and the terminal T4 are formed, and then a plurality of electronic components 100 are obtained by performing a dicing process.

### 5 Characteristics

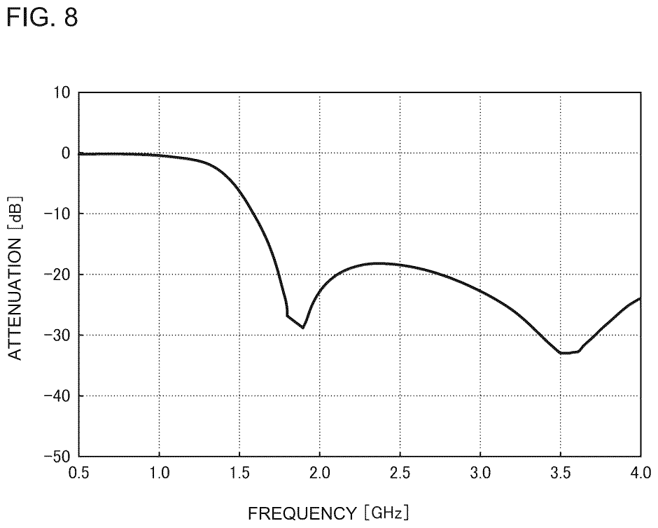

FIG. 8 illustrates the attenuation-frequency characteristics of the electronic component 100. In the electronic component 100, it is possible to obtain attenuation-frequency characteristics similar to those of an LC filter in which the inductor L3 in FIG. 7 is formed separately from the first inductor L1 and the second inductor L2. In the electronic component 100, an attenuation pole determined by the capacitance of the second capacitor C2 and the mutual inductance caused by cumulative connection between the first inductor L1 and the second inductor L2 is generated. In addition, the electronic component 100 can reduce the insertion loss of the LC filter.

### 6 Effects

The electronic component 100 according to the first embodiment includes the substrate 1, the insulating layer 2, the first inductor L1, and the second inductor L2. The insulating layer 2 is provided on the substrate 1. The first inductor L1 includes the spiral-shaped first conductor pattern portion 11 provided in the insulating layer 2. The second inductor L2 includes the spiral-shaped second conductor pattern portion 12 provided in the insulating layer 2. The insulating layer 2 includes the interlayer insulating film 23 that covers the first inductor L1, and the second conductor pattern portion 12 of the second inductor L2 is provided on the interlayer insulating film 23. The second conductor pattern portion 12 of the second inductor L2 includes the first portion 121 that overlaps the first conductor pattern portion 11 of the first inductor L1 in plan view in the thickness direction D1 of the substrate 1 and the second portion 122 that does not overlap the first conductor pattern portion 11 of the first inductor L1 in plan view in the thickness direction D1 of the substrate 1. The second inductor L2 includes the third conductor pattern portion 13 formed in the interlayer insulating film 23, and at least a portion of the third conductor pattern portion 13 overlaps the second portion 122 of the second conductor pattern portion 12.

In the structure described above, it is possible to achieve size reduction while reducing characteristic degradation. More specifically, the resistance value of the second inductor L2 can be reduced and the Q value can be improved because the second inductor L2 includes the third conductor pattern portion 13 in the electronic component 100 according to the first embodiment, and accordingly, it is possible to achieve size reduction while reducing characteristic degradation.

In addition, in the electronic component 100 according to the first embodiment, the first inductor L1 further includes a fourth conductor pattern portion 14 formed in the interlayer insulating film 23. The fourth conductor pattern portion 14 overlaps a portion of the first conductor pattern portion 11 that does not overlap the second conductor pattern portion 12 of the second inductor L2 in plan view in the thickness direction D1 of the substrate 1.

In the structure described above, it is possible to achieve size reduction while further reducing characteristic degradation. More specifically, since the electronic component 100 according to the first embodiment can reduce the resistance value of the first inductor L1 and improve the Q value of the first inductor L1, it is possible to achieve size reduction while further reducing characteristic degradation.

### Second Embodiment

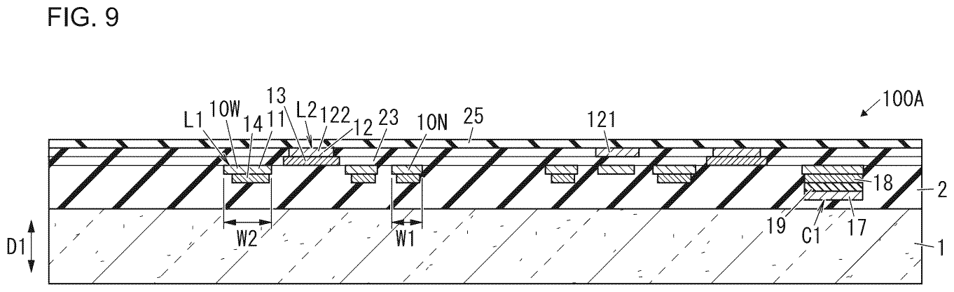

An electronic component 100A according to a second embodiment will be described with reference to FIG. 9. In the electronic component 100A according to the second embodiment, components that are the same as those of the electronic component 100 according to the first embodiment (see FIGS. 1 to 7) are denoted by the same reference numerals and descriptions thereof are omitted.

As illustrated in FIG. 9, the electronic component 100A differs from the electronic component 100 according to the first embodiment in that the width of the third conductor pattern portion 13 is greater than the width of the second conductor pattern portion 12 in plan view in the thickness direction D1 of the substrate 1 in the second portion 122 of the second conductor pattern portion 12 of the second inductor L2.

In the electronic component 100A according to the second embodiment, it is possible to achieve size reduction while further reducing characteristic degradation as in the electronic component 100 according to the first embodiment. In addition, in the electronic component 100A according to the second embodiment, the resistance value of the second inductor L2 can be reduced and the characteristics can be improved.

### Modifications

The first and second embodiments and the like described above are only embodiments of the present disclosure. The first and second embodiments and the like described above can be variously changed.

### Aspects

This specification discloses the following aspects.

An electronic component (100, 100A) according to a first aspect comprises a substrate (1), an insulating layer (2), a first inductor (L1), and a second inductor (L2). The insulating layer (2) is provided on the substrate (1). The first inductor (L1) includes a spiral-shaped first conductor pattern portion (11) provided in the insulating layer (2). The second inductor (L2) includes a spiral-shaped second conductor pattern portion (12) provided in the insulating layer (2). The insulating layer (2) includes an interlayer insulating film (23) that covers the first inductor (L1). The second conductor pattern portion (12) of the second inductor (L2) is provided on the interlayer insulating film (23). The second conductor pattern portion (12) of the second inductor (L2) includes a first portion (121) that overlaps the first conductor pattern portion (11) of the first inductor (L1) in plan view in a thickness direction (D1) of the substrate (1) and a second portion (122) that does not overlap the first conductor pattern portion (11) of the first inductor (L1) in plan view in the thickness direction (D1) of the substrate (1). The second inductor (L2) includes a third conductor pattern portion (13) formed in the interlayer insulating film (23), at least a portion of the third conductor pattern portion (13) overlapping the second portion (122) of the second conductor pattern portion (12).

According to this aspect, it is possible to achieve size reduction while reducing characteristic degradation.

An electronic component (100, 100A) according to a second aspect is the electronic component (100, 100A) according to the first aspect wherein the first inductor (L1) further includes a fourth conductor pattern portion (14). The fourth conductor pattern portion (14) is formed in the interlayer insulating film (23). The fourth conductor pattern portion (14) overlaps a portion of the first conductor pattern portion (11) that does not overlap the second conductor pattern portion (12) of the second inductor (L2) in plan view in the thickness direction (D1) of the substrate (1).

According to this aspect, it is possible to achieve size reduction while further reducing characteristic degradation.

An electronic component (100, 100A) according to a third aspect is the electronic component (100, 100A) according to the first or second aspect wherein, in plan view in the thickness direction (D1) of the substrate (1), a plurality of portions of the second conductor pattern portion (12) and a plurality of portions of the first conductor pattern portion (11) are alternately arranged in a width direction of the second conductor pattern portion (12) and the first conductor pattern portion (11).

According to this aspect, it is possible to increase the Q value of the first inductor (L1) and the Q value of the second inductor (L2) and improve the characteristics.

An electronic component (100, 100A) according to a third aspect is the electronic component (100, 100A) according to any one of the first to third aspects wherein a conductor pattern portion (10) that is at least one of the first conductor pattern portion (11) and the second conductor pattern portion (12) includes a narrow portion (10N) having a first width (W1) and a wide portion (10W) having a second width (W2) greater than the first width (W1). Of a first end (101) and a second end (102) of the conductor pattern portion (10), the first end (101) is closer to a center, and the narrow portion (10N) has the first end (101). The wide portion (10W) includes the second end (102). At least one of the first portion (121) of the second conductor pattern portion (12) of the second inductor (L2) and a portion of the first inductor (L1) that overlaps the first portion (121) includes a portion of the narrow portion (10N).

According to this aspect, it is possible to reduce the parasitic capacitance generated between the first inductor (L1) and the second inductor (L2) and reduce characteristic degradation.

An electronic component (100, 100A) according to a fifth aspect is the electronic component (100, 100A) according to any one of the first to fourth aspects, further comprising a via conductor (V12) formed in the interlayer insulating film (23), the via conductor being disposed between the first inductor (L1) and the second inductor (L2). In the electronic component (100), the first inductor (L1) and the second inductor (L2) are cumulatively connected to each other by the via conductor (V12).

According to this aspect, since mutual inductance between the first inductor (L1) and the second inductor (L2) is formed, the number of inductors can be reduced.

An electronic component (100, 100A) according to a sixth aspect is the electronic component (100, 100A) according to any one of the first to fifth aspects wherein an area of the first portion (121) of the second conductor pattern portion (12) is less than an area of the second portion (122) of the second conductor pattern portion (12) in plan view in the thickness direction (D1) of the substrate (1).

According to this aspect, it is possible to reduce the parasitic capacitance generated between the first inductor (L1) and the second inductor (L2) and reduce characteristic degradation.

An electronic component (100, 100A) according to a seventh aspect is the electronic component (100, 100A) according to any one of the first to sixth aspects wherein the first conductor pattern portion (11) has a first end (11a) closer to a center and a second end (11b) closer to an outer periphery and the second conductor pattern portion (12) has a first end (12a) closer to the center and a second end (12b) closer to the outer periphery. The second portion (122) of the second conductor pattern portion (12) of the second inductor (L2) is closer to the second end (12b) of the second conductor pattern portion (12) than to the first end (12a) of the second conductor pattern portion (12).

According to this aspect, the characteristics of the second inductor (L2) can be improved.

An electronic component (100) according to an eighth aspect is the electronic component (100, 100A) according to any one of the first to seventh aspects. In plan view in the thickness direction (D1) of the substrate (1), a width (W3) of the third conductor pattern portion (13) is less than a width (W4) of the first conductor pattern portion (13) in the second portion (122) of the second conductor pattern portion (12) of the second inductor (L2).

According to this aspect, it is possible to reduce the parasitic capacitance generated between the third conductor pattern portion (13) and the first inductor (L1) and improve the characteristics.

An electronic component (100) according to a ninth aspect is the electronic component (100, 100A) according to any one of the first to seventh aspects. In plan view in the thickness direction (D1) of the substrate (1), a width (W3) of the third conductor pattern portion (13) is greater than a width (W4) of the first conductor pattern portion (11) in the second portion (122) of the second conductor pattern portion (12) of the second inductor (L2).

According to this aspect, the resistance value of the second inductor (L2) can be reduced, and the characteristics can be improved.

An electronic component (100, 100A) according to a tenth aspect is the electronic component (100, 100A) according to any one of the first to ninth aspects, further comprising capacitors (C1, C2). Each of the capacitors (C1, C2) includes a pair of electrodes (17, 18) provided in the insulating layer (2). Each of the capacitors (C1, C2) is included in an LC filter together with the first inductor (L1) and the second inductor (L2). The pair of electrodes (17, 18) of each of the capacitors (C1, C2) is located closer to the substrate (1) than is the first inductor (L1) in the thickness direction (D1) of the substrate (1).

An electronic component (100, 100A) according to an eleventh aspect is the electronic component (100, 100A) according to the tenth aspect wherein the pair of electrodes (17, 18) does not overlap the first inductor (L1) or the second inductor (L2) in plan view in the thickness direction (D1) of the substrate (1).

An electronic component (100, 100A) according to a twelfth aspect is the electronic component (100, 100A) according to the eleventh aspect wherein the pair of electrodes (17, 18) of each of the capacitors (C1, C2) is located outside the second inductor (L2) in plan view in the thickness direction (D1) of the substrate (1).

According to this aspect, since magnetic fields generated by the first inductor (L1) and the second inductor (L2) are less likely to be blocked by the pair of electrodes (17, 18) of each of the capacitors (C1, C2), characteristic degradation can be reduced.

What is claimed is:

1. An electronic component comprising:
a substrate;
an insulating layer on the substrate;
a first inductor comprising a spiral-shaped first conductor pattern in the insulating layer; and
a second inductor comprising a spiral-shaped second conductor pattern in the insulating layer,
wherein the insulating layer comprises an interlayer insulating film that covers the first inductor,
wherein the second conductor pattern is on the interlayer insulating film,
wherein the second conductor pattern portion comprises:
a first portion that overlaps the first conductor pattern in a plan view of the substrate, and
a second portion that does not overlap the first conductor pattern in the plan view of the substrate, and
wherein the second inductor comprises a third conductor pattern in the interlayer insulating film, and at least a portion of the third conductor pattern overlaps the second portion of the second conductor pattern in the plan view of the substrate.

2. The electronic component according to claim 1, wherein the first inductor further comprises:
a fourth conductor pattern in the interlayer insulating film, the fourth conductor pattern overlapping a portion of the first conductor pattern that does not overlap the second conductor pattern in the plan view of the substrate.

3. The electronic component according to claim 1,
wherein, in the plan view of the substrate, a plurality of portions of the second conductor pattern and a plurality of portions of the first conductor pattern are alternately arranged in a width direction of the second conductor pattern and the first conductor pattern.

4. The electronic component according to claim 1,
wherein the first conductor pattern or the second conductor pattern comprises:
a narrow portion having a first width,
a wide portion having a second width greater than the first width, and
a first end that is closer to a center of the substrate than a second end,
wherein the narrow portion comprises the first end and the wide portion comprises the second end, and
wherein the first portion of the second conductor pattern or a portion of the first inductor that overlaps the first portion comprises a portion of the narrow portion.

5. The electronic component according to claim 1, further comprising:
a via conductor in the interlayer insulating film, the via conductor being between the first inductor and the second inductor,
wherein the first inductor and the second inductor are cumulatively connected to each other by the via conductor.

6. The electronic component according to claim 1,
wherein an area of the first portion of the second conductor pattern is less than an area of the second portion of the second conductor pattern in the plan view of the substrate.

7. The electronic component according to claim 1,
wherein the first conductor pattern has a first end closer to a center of the substrate than a second end, and the second end is closer to an outer periphery of the substrate than the first end,
wherein the second conductor pattern has a first end closer to the center of the substrate than a second end, and the second end is closer to the outer periphery of the substrate than the first end, and
wherein the second portion of the second conductor pattern is closer to the second end of the second conductor pattern than to the first end of the second conductor pattern.

8. The electronic component according to claim 1,
wherein, in the plan view of the substrate, a width of the third conductor pattern is less than a width of the first conductor pattern in the portion of the third conductor pattern that overlaps the second portion of the second conductor pattern.

9. The electronic component according to claim 1,
wherein, in the plan view of the substrate, a width of the third conductor pattern is greater than a width of the first conductor pattern in the portion of the third conductor pattern that overlaps the second portion of the second conductor pattern in plan view.

10. The electronic component according to claim 1, further comprising:
a capacitor comprising a pair of electrodes in the insulating layer,
an LC filter comprising the capacitor, the first inductor, and the second inductor,
wherein the pair of electrodes of the capacitor is located closer to the substrate in the thickness direction of the substrate than the first inductor.

11. The electronic component according to claim 10,
wherein the pair of electrodes does not overlap the first inductor or the second inductor in the plan view of the substrate.

12. The electronic component according to claim 11,
wherein the pair of electrodes is located outside the second inductor in the plan view of the substrate.
